(19) United States
(12) Patent Application Publication
(10) Pub. No.: US 2026/0129784 A1
(43) Pub. Date: May 7, 2026

(54) QUICK-PRESS SNAP-ON LOCKING DEVICE

(71) Applicant: Aivres Systems Inc., Fremont, CA (US)

(72) Inventor: Chiaming CHANG, New Taipei City (TW)

(73) Assignee: Aivres Systems Inc., Fremont, CA (US)

(21) Appl. No.: 19/436,272

(22) Filed: Dec. 30, 2025

(51) Int. Cl. H05K 7/14; G06F 1/183

(52) U.S. Cl. CPC H05K 7/1489; G06F 1/183; H05K 7/1417

(57) ABSTRACT

A locking device includes an adjustable base assembly, which includes a rotation assembly and a linear guide rail, and a locking assembly mounted on the adjustable base assembly. The locking device includes one or more spring tabs configured to engage and disengage with one or more slots provided on one or more frame panels, an abutment block, and a sliding rod assembly. The abutment block is configured to push, in response to a force, the one or more spring tabs outward, thereby causing engagement of the one or more spring tabs with the one or more slots. The sliding rod assembly is configured to move with the abutment block and provide a first stable position for a locked state and a second stable position for an unlocked state. The adjustable base assembly is configured to adjust a position and an orientation of the locking assembly relative to the frame panels.

### TECHNICAL FIELD

This patent application relates to components for electronic systems and, in particular, to a locking mechanism that enhances the mechanical stability of components within electronic systems.

### BACKGROUND

Computer systems are assembled from different electronic components and devices that are communicatively interconnected and housed in a common chassis or enclosure. To interconnect the components for the routing of electronic data signals and electrical power, one or more rigid printed boards (PCBs) can be accommodated in the enclosure defined by the chassis. The PCB may include a planar substrate made of an insulative material such as phenolic resin having electrically conductive traces disposed on the planar surfaces or embedded in the laminated structure of the board. Electronic devices, such as resistors, capacitors, and integrated circuits, can be mounted to the planar surface of the printed circuit board and can be communicatively connected by the conductive traces. The arrangement and cooperative operation of the electronic components are responsible for the computational and processing functionality of the computer system.

Chassis are typically mounted in racks to provide a stable and organized framework for housing computer systems. Within the chassis, individual components or parts are often arranged into modules, such as power supply units (PSUs), storage devices (e.g., memory and/or hard drives), processing units (e.g., central processing units (CPUs) and graphics processing units (GPUs)), cooling devices (e.g., cooling fans, liquid cooling devices), expansion interfaces, and more. In some implementations, these modules are mounted in trays (or other suitable containers), which are housed within the chassis.

To prevent the equipment from sliding out of the rack, a mechanism may be provided to secure the equipment to the casing. Conventional designs of these mechanisms can present challenges. For example, the mechanical components may require a large rotational radius to slide a latch into place. Other designs require a user to manually rotate a cam latch, which can be difficult to operate in narrow spaces.

### SUMMARY OF THE DISCLOSURE

A locking device is provided, offering several advantages. The locking device incorporates a quick-press, snap-on locking and quick-release mechanism, enabling efficient assembly and disassembly of removable modular devices in electronic systems, such as computer or server systems, while reducing labor costs. The locking device can be operated with a simple press to lock or unlock the modular device(s) from the casing, making maintenance more convenient. Additionally, the compact structural design of the locking device minimizes the required installation space.

In an exemplary embodiment, a locking device includes an adjustable base assembly that includes a rotation assembly and a linear guide rail, and a locking assembly mounted on the adjustable base assembly. The locking assembly includes one or more spring tabs configured to engage and disengage with one or more slots provided on one or more frame panels, an abutment block, and a sliding rod assembly. The abutment block is movable in an axial direction relative to the one or more spring tabs and configured to push, in response to a force, the one or more spring tabs outward, thereby causing engagement of the one or more spring tabs with the one or more slots, and wherein the abutment block is connected to the sliding rod assembly. The sliding rod assembly is configured to move with the abutment block and provide a first stable position for a locked state and a second stable position for an unlocked state. The adjustable base assembly is configured to adjust a position and an orientation of the locking assembly relative to the one or more slots.

According to an embodiment of the locking device, the sliding rod assembly includes a lower rod, an upper rod, and a rod housing fitted over the upper rod. One end of the lower rod is connected to one end of the abutment block, and the lower rod is rotatable relative to the abutment block. The other end of the lower rod is in contact with one end of the upper rod. The lower rod, the upper rod, and the rod housing are aligned along the axial direction. The lower rod and the upper rod are configured to slide along the axial direction relative to the rod housing.

According to an embodiment of the locking device, the lower rod includes a wavy surface on one end, the upper rod includes a reciprocal wavy surface on one end, and the wavy surface of the lower rod is oriented toward the reciprocal wavy surface of the upper rod in the sliding rod assembly and the reciprocal wavy surface of the upper rod is configured to mate and engage the wavy surface of the low rod.

According to an embodiment of the locking device, the sliding rod assembly further includes a spring. The spring is positioned between the lower rod and the upper rod.

According to an embodiment of the locking device, at least one of the lower rod or the upper rod comprises a recessed hole, the recessed hole being configured to receive the spring when compressed.

According to an embodiment of the locking device, the lower rod includes a cylindrical column and at least one plate attached to side wall of the cylindrical column. A side wall of the rod housing includes a curved edge, and wherein in the sliding rod assembly, the at least one plate on the lower rod is in contact with the curved edge of the rod housing.

According to an embodiment of the locking device, the curved edge of the rod housing is provided a plurality of grooves to provide rotational limits. The plurality of grooves comprise first sections having a first depth and second sections having a second depth, the first and second sections are alternately arranged along the curved edge of the rod housing.

According to an embodiment of the locking device, the at least one plate on the lower rod comprises three plates spaced apart by 120 degrees, and the curved edge of the rod housing is provided with three first sections and three second sections.

According to an embodiment of the locking device, one edge along the linear guide rail includes a series of repetitive structures configured to provide positional limits to the adjustable base assembly along a linear direction.

According to an embodiment of the locking device, the rotation assembly includes a plurality of hemispherical structures and one or more spring arm structures configured to provide rotational limits to the adjustable base assembly.

According to an embodiment of the locking device, the abutment block further includes at least one handle positioned on at least one side of the abutment block. A bracket mounted outside the sliding rod assembly includes at least one elongated slot configured to guide movement of the handle on the abutment block.

According to an embodiment of the locking device, the one or more spring tabs include a single spring tab, configured to lock a single modular device within a casing.

According to an embodiment of the locking device, the one or more spring tabs include two or more spring tabs, configured to lock two or more modular device within a casing at the same time.

According to an embodiment of the locking device, the one or more spring tabs are fixed to a casing of a computer system or a server system through the adjustable base assembly. One or more modular devices are locked in the casing of the computer system or the server system based on the one or more spring tabs engaging with the one or more slots on the one or more modular devices.

In a further exemplary embodiment, a framework for housing one or more computer systems is provided, which includes a casing, one or more modular devices provided with one or more slots, and a locking device configured to lock and unlock the one or more modular devices within the casing. The one or more modular devices are removable from the casing. The locking device includes an adjustable base assembly that includes a rotation assembly and a linear guide rail, and a locking assembly mounted on the adjustable base assembly. The locking assembly includes one or more spring tabs configured to engage and disengage with one or more slots, an abutment block, and a sliding rod assembly. The abutment block is movable in an axial direction relative to the one or more spring tabs and configured to push, in response to a force, the one or more spring tabs outward, thereby causing engagement of the one or more spring tabs with the one or more slots, and wherein the abutment block is connected to the sliding rod assembly. The sliding rod assembly is configured to move with the abutment block and provide a first stable position for a locked state and a second stable position for an unlocked state. The adjustable base assembly is configured to adjust a position and an orientation of the locking assembly relative to the one or more slots.

According to an embodiment of the framework, the sliding rod assembly includes a lower rod, an upper rod, and a rod housing fitted over the upper rod. One end of the lower rod is connected to one end of the abutment block, and the lower rod is rotatable relative to the abutment block. The other end of the lower rod is in contact with one end of the upper rod. The lower rod, the upper rod, and the rod housing are aligned along the axial direction. The lower rod and the upper rod are configured to slide along the axial direction relative to the rod housing.

According to an embodiment of the framework, the lower rod includes a wavy surface on one end, the upper rod includes a reciprocal wavy surface on one end, and the wavy surface of the lower rod is oriented toward the reciprocal wavy surface of the upper rod in the sliding rod assembly and the reciprocal wavy surface of the upper rod is configured to mate and engage the wavy surface of the low rod.

According to an embodiment of the framework, the sliding rod assembly further includes a spring. The spring is positioned between the lower rod and the upper rod.

According to an embodiment of the framework, at least one of the lower rod or the upper rod includes a recessed hole, the recessed hole being configured to receive the spring when compressed.

In yet a further exemplary embodiment, a method for assembling a computer or server system including one or more modular devices that are removable from a casing is provided, which includes providing the casing of the computer or server system and the one or more modular devices, the one or more modular devices provided with one or more slots, providing a locking device connected to the casing, adjust a position and a rotation of the locking device to align with the one or more slots, and operate the locking device to lock or unlock the one or more modular devices to the casing. The locking device includes an adjustable base assembly that includes a rotation assembly and a linear guide rail, and a locking assembly mounted on the adjustable base assembly. The locking assembly includes one or more spring tabs configured to engage and disengage with one or more slots, an abutment block, and a sliding rod assembly. The abutment block is movable in an axial direction relative to the one or more spring tabs and configured to push, in response to a force, the one or more spring tabs outward, thereby causing engagement of the one or more spring tabs with the one or more slots, and wherein the abutment block is connected to the sliding rod assembly. The sliding rod assembly is configured to move with the abutment block and provide a first stable position for a locked state and a second stable position for an unlocked state. The adjustable base assembly is configured to adjust a position and an orientation of the locking assembly relative to the one or more slots.

### BRIEF DESCRIPTION OF THE DRAWINGS

FIG. 1A is a front perspective view of a rack server, in accordance with certain embodiments.

FIG. 1B is an enlarged view showing the locking device in a secured position with respect to the modular devices.

FIG. 2A is a perspective view of the locking device, in accordance with certain embodiments.

FIG. 2B illustrates an adjustable base assembly, in accordance with certain embodiments.

FIG. 2C shows a locking assembly, in accordance with certain embodiments.

FIG. 2D provides an exploded view of the locking device, in accordance with certain embodiments.

FIGS. 3A-3E illustrate various components of an adjustable base assembly, in accordance with certain embodiments.

FIGS. 4A-4C illustrate various components of a locking assembly, in accordance with certain embodiments.

FIGS. 4D-4H illustrate various components of a sliding rod assembly, in accordance with certain embodiments.

FIGS. 5A-5B illustrate the locking device in a stable unlocked state and a stable locked state, respectively, in accordance with certain embodiments.

FIGS. 6A-6E illustrate a dynamic process of using the locking device, in accordance with certain embodiments.

FIG. 7A illustrates a rotation assembly, in accordance with certain embodiments.

FIGS. 7B-7E illustrate example rotational operation of the rotation assembly, in accordance with certain embodiments.

FIG. 8 is a flow chart illustrating a method for assembling a computer/server system utilizing a locking device, in accordance with certain embodiments.

### DETAILED DESCRIPTION

The following detailed description is exemplary in nature and is not intended to limit the disclosure or the application and uses of the described embodiments. Furthermore, there is no intention to be bound by any expressed or implied theory presented in the preceding background, summary and brief description of the drawings, or the following detailed description. Numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

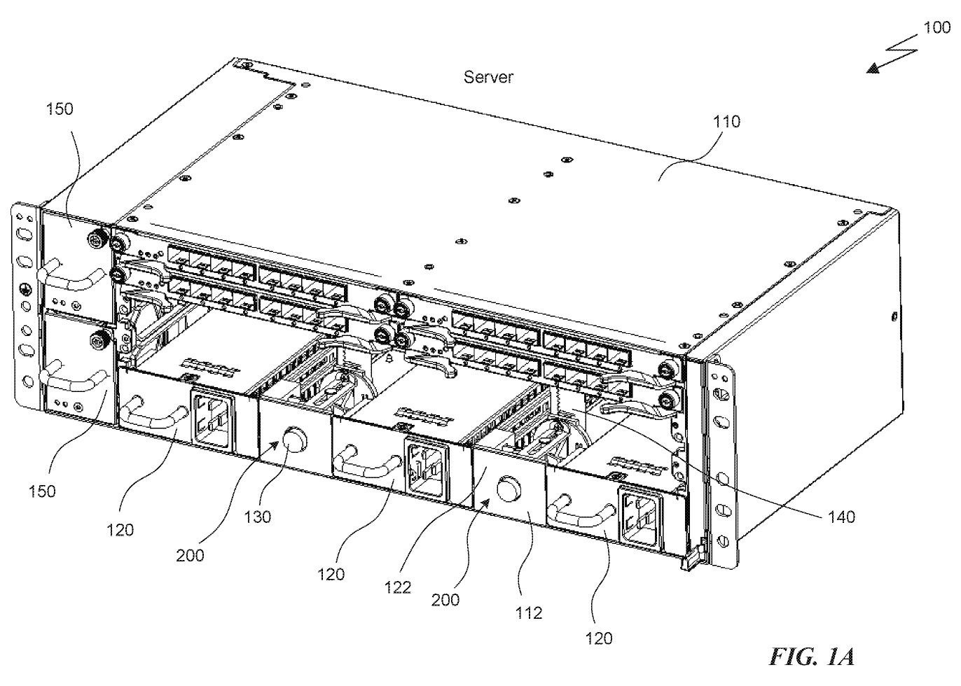

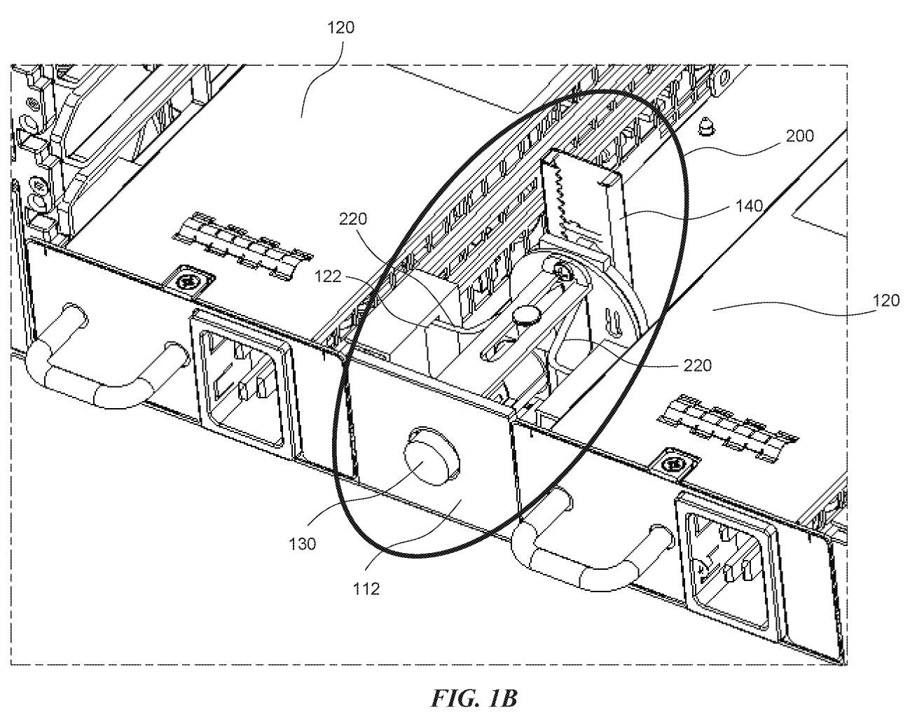

Now referring to the drawings, where whenever possible like reference numbers will refer to like elements. FIG. 1A is a front perspective view of a rack server 100, in accordance with certain embodiments. The rack server 100 includes a casing 110 in which various modular devices (e.g., power supply units) and other components (e.g., motherboards, connectors, etc.) are mounted. The modular devices may be configured as units housed within movable containers, such as the modular devices 120 and 150. The modular devices 120 and 150 may be inserted into and removed from the casing 110.

In FIG. 1A, the modular devices 120 can be locked within the casing 110 by one or more locking devices 200. Each locking device employs a quick-press, snap-on locking mechanism. In addition, the position of the locking device within the casing 110 may be adjustable through additional structural features.

The locking device 200 can be used in various applications. In certain embodiments, the locking device 200 can be used in an electronic device, such as a computer system, comprised of various electronic components and hardware that are cooperatively interconnected and assembled together, which may be housed in a common case or enclosed chassis. A chassis can be a box-like structure made of formed sheet metal or molded plastic that defines an internal space or chassis volume for the internal components and hardware of the system.

In certain embodiments, the locking device 200 can be used in a framework, such as a rack, where multiple computer systems, servers, and networking devices are mounted, such as in data centers. For example, the aforementioned computer system can be configured for integration with a larger network or system, and the chassis (which encloses the computer system or a suitable part thereof) may be designed for mounting into a rack alongside similar computer systems. In this configuration, the casing 110 may represent a rack of a server, and the modular devices 120 may represent the computer systems, chassis, or other suitable components (e.g., one or more PSUs, memory, hard drives, GPUs, CPUs and the like) packaged into modules. However, it will be appreciated that the casing 110 and modular devices 120 can represent other suitable components in a broad range of applications, as long as they provide similar functions that can be used in connection with the locking device 200 to achieve the functions disclosed herein.

In FIG. 1A, a locking device 200 is arranged between two modular devices 120. The locking device 200 includes a press button 130 that, when pressed, engages or releases a locking mechanism in the locking device 200. When engaged, the modular devices 120 are securely locked inside the casing 110. When released, the locking mechanism disengages, allowing the modular devices 120 to be freely pulled out and removed from the casing 110.

Side panels of the modular devices 120 are equipped with slots 122, into which the locking mechanism of the locking device 200 can be engaged or released. Although described and illustrated as slots, other configurations, such as holes, notches, recesses, and the like, may also be used to interface with the locking device 200 and interact with the locking mechanism. Additionally and/or alternatively, other suitable frame panels of the modular devices, such as the top or bottom panels, may be equipped with slots 122 to cooperate with the locking mechanism of the locking device 200.

The locking device 200 includes a base bracket 140. In certain embodiments, the base bracket 140 of the locking device 200 is fixed to the frame of the casing 110. For example, at least one edge (e.g., top or bottom edge) of the base bracket 140, as seen in this view, can be welded or secured with adhesive, screws, rivets and the like to the top or bottom panel of the casing 110. Additionally and/or alternatively, although not depicted in FIG. 1A, a partition may be provided in the middle of the casing 110, to which the base bracket 140 is affixed. For example, a bottom of the base bracket 140 may be fixed to the partition.

The press button 130 can be set on the front panel 112 of the casing 110. For example, the front panel 112 may include a cutout, such as a through-hole, exposing the button 130. When the locking device 200 is disengaged, the modular devices 120 can be either pulled out from or inserted into the casing 110.

FIG. 1B is an enlarged view showing the locking device 200 in a secured position with respect to the modular devices 120.

As shown in FIG. 1B, a pair of spring tabs 220 are fixed on the base bracket 140 of the locking device 200. In the locked state, the spring tabs 220 are in an expanded position, with their top ends inserted into the slot 122 on the side panels of the modular devices 120, thereby securing both modular devices 120 in place. However, it will be understood that the present disclosure is not limited to a specific number of spring tabs 220. For example, a single spring tab 220 may be used to secure a single modular device 120. In other embodiments, more than two spring tabs 220 may be implemented.

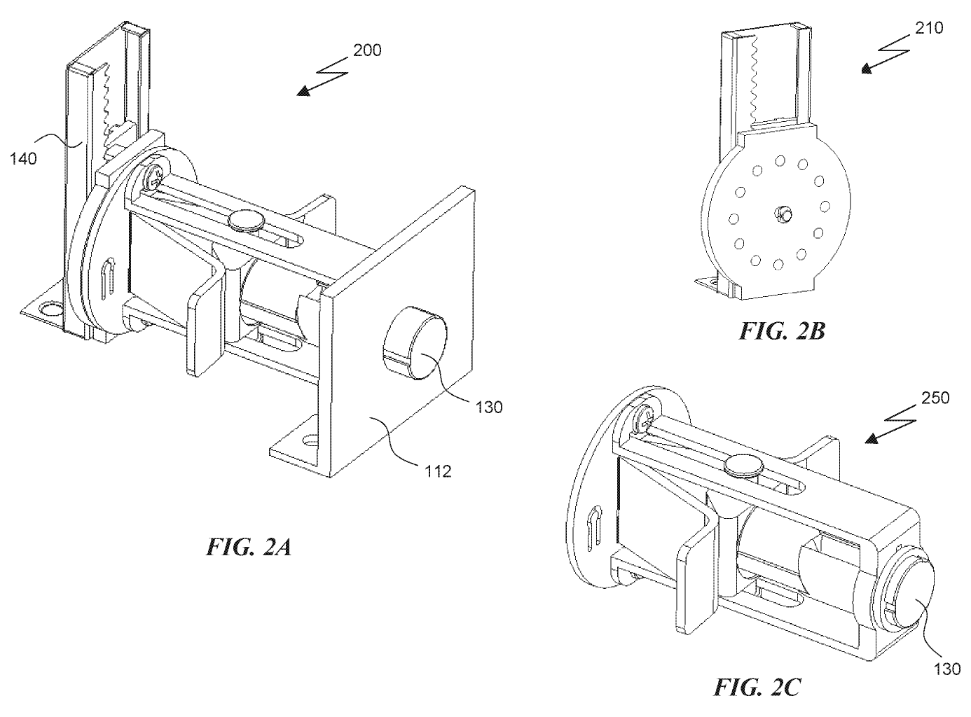

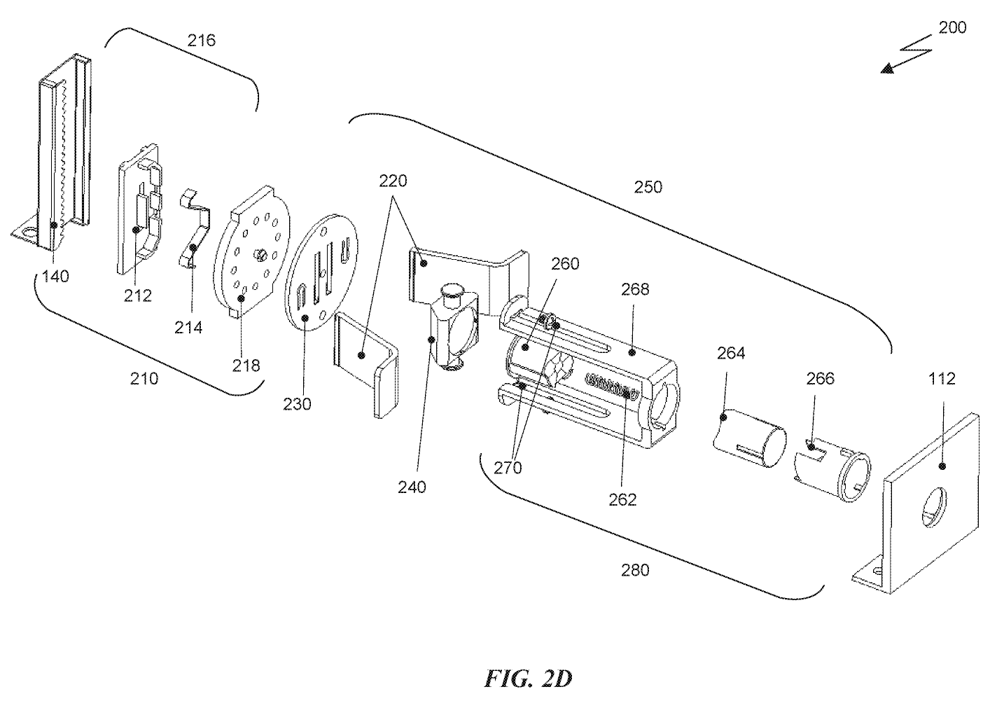

FIG. 2A is a perspective view of the locking device 200. The locking device 200 includes multiple subsystems. Specifically, FIG. 2B illustrates an adjustable base assembly 210, and FIG. 2C shows a locking assembly 250.

FIG. 2D provides an exploded view of the locking device 200, in accordance with certain embodiments.

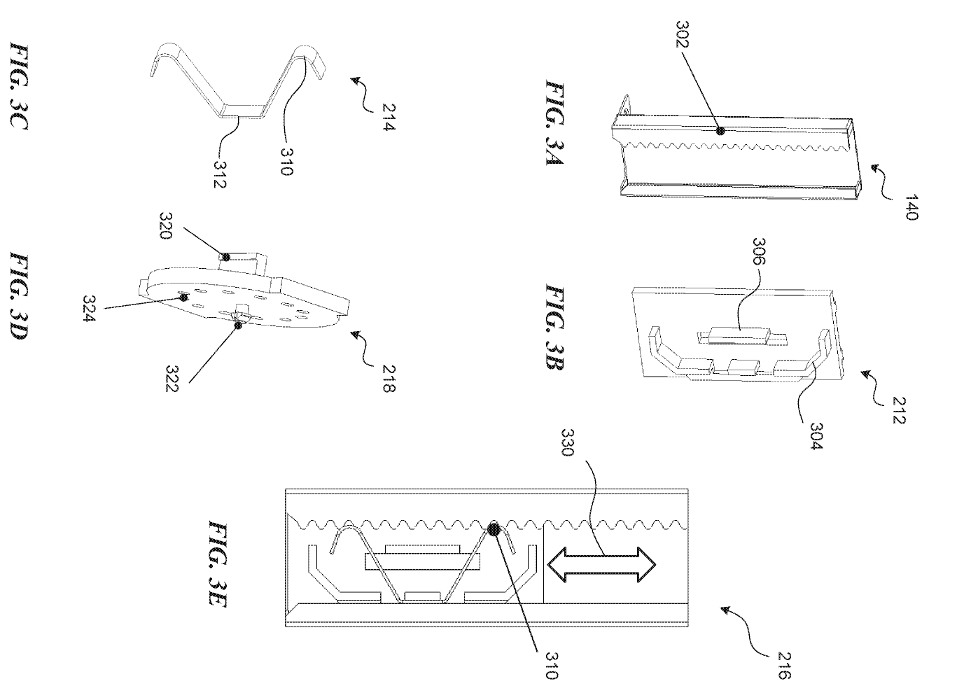

The adjustable base assembly 210 includes the base bracket 140, a slider base 212, a spring clip 214, and a base frame 218. The base bracket 140, the slider base 212, and the spring clip 214 may together form a subassembly 216 configured to be slidable in a direction defined by the base bracket 140. Further details of these components will be described with reference to FIGS. 3A-3E.

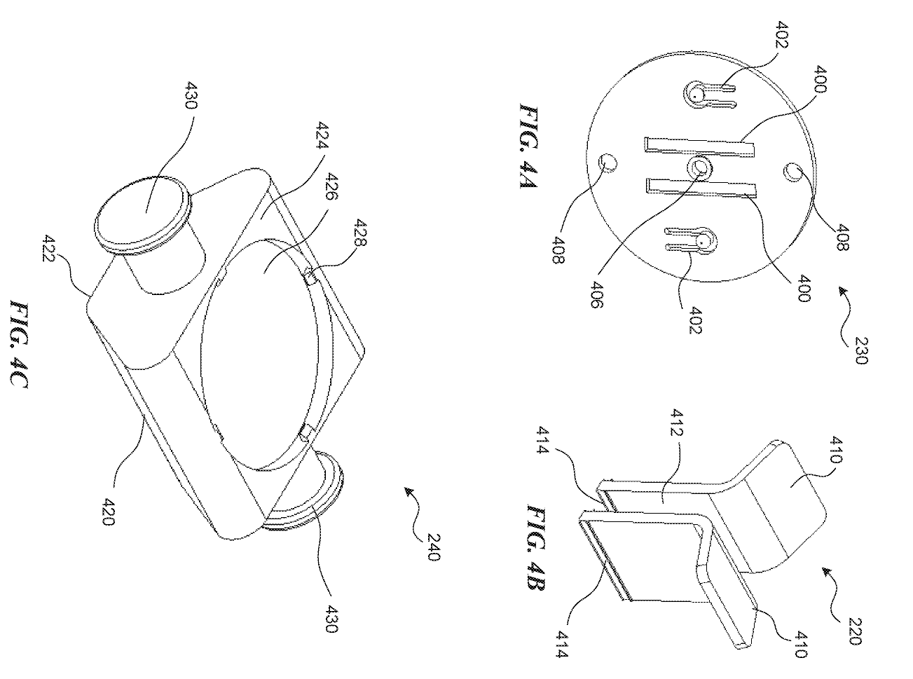

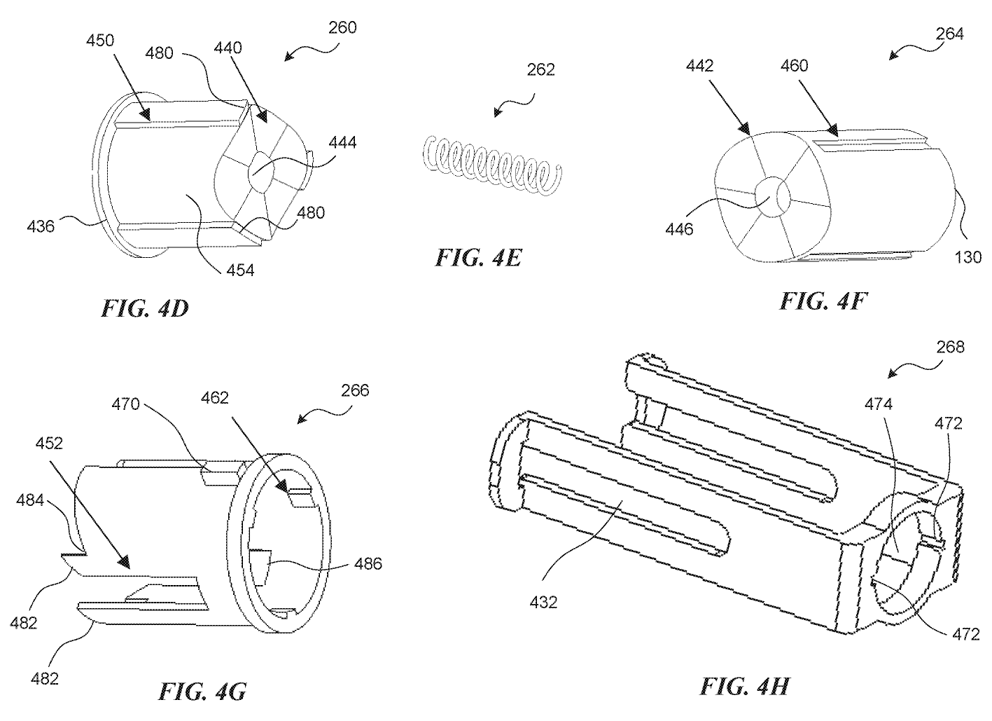

The locking assembly 250 includes various components, such as a rotary plate 230, the pair of spring tabs 220, an abutment block 240, and a sliding rod assembly 280. The rotary plate 230, the pair of spring tabs 220, and the abutment block 240 will be described with reference to FIGS. 4A-4C. The sliding rod assembly 280 further includes various components, such as a lower rod 260, an upper rod 264, a rod housing 266, and more, which will be described with reference to FIGS. 4D-4H.

The front panel 112 can be affixed to a front side of the casing 110, as shown in FIG. 1A, such that the locking device 200 is enclosed within the casing 110. It should be noted that the front panel 112 may alternatively be formed integrally with the casing 110 rather than provided as a separate component.

As shown in FIG. 3A, the base bracket 140 may be implemented as a sliding rail bracket having a linear guide rail with edges configured to allow a corresponding sliding assembly to move along the direction of the rail. The base of the sliding assembly is confined within the guide rail to ensure stable guided movement. Along one side of the rail, a series of repeating sawtooth structures 302 (or other suitable repetitive structures, such as wavy structures) is provided to engage with a corresponding structure specially formed on the sliding assembly, thereby providing a limiting function that positions the sliding assembly at designated locations (e.g., at valley portions of the sawtooth structures 302).

The sliding assembly may be formed by the slider base 212 and the spring clip 214. As shown in FIG. 3B, the slider base 212 includes protruding structures 304 that corresponds to the serpentine shape of the spring clip 214. The cooperation between these two components allows the sliding assembly to be secured on the guide rail of the base bracket 140. As shown in FIG. 3C, the spring clip 214 includes one end 312 configured to abut the protruding structures 304, and a plurality of U-shaped structures 310 (or other suitable structures) configured to engage with the valley portions of the sawtooth structures 302. In FIG. 3E, the sliding assembly is assembled with the base bracket 140. Arrow 330 indicates the direction along which the sliding assembly can move relative to the base bracket 140. The U-shaped structures 310 allow the sliding assembly to be stably positioned at corresponding locations along the base bracket.

Additionally, the slider base 212 includes protruding structures 306, which are used to secure the base frame 218. As shown in FIG. 3E, the bottom of the base frame 218 includes a hook structure that can engage with the protruding structures 306 to secure the base frame 218 to the sliding assembly. On the opposite side of the sliding assembly, a plurality of hemispherical structures 324 are provided to limit the movement of a rotary structure positioned thereon. A central barb 322 is included to engage with the rotary structure. For example, the rotary structure includes the rotary plate 230 as shown in FIG. 4A.

In FIG. 4A, the rotary plate 230 includes a through hole 406 at its central portion, which cooperates with the central barb 322 on the base frame 218 to secure the rotary plate 230 to the base frame 218 while allowing it to rotate. On one side of the rotary plate 230, one or more spring arm structures 402 (e.g., the U-shaped structures) are provided, which engage with the hemispherical structures 324 on the base frame 218 during rotation to achieve rotational limiting. On the opposite side of the base frame 218, structures 400 are configured to accommodate the spring tabs 220. In addition, the rotary plate 230 includes two screw holes 408, which are configured to secure the bracket 268 of the locking assembly 250 using screws 270 (e.g., shown in FIG. 2D).

As shown in FIG. 4B, the spring tabs 220 are generally L-shaped and arranged opposite one another in a wing-like configuration in the embodiment shown. It will be appreciated that the configuration of the spring tabs 220 shown in FIG. 4B is by way of example and that other configurations may be employed. A gap 412 is provided between the two spring tabs 220. When a component (e.g., the abutment block 240 shown in FIG. 4C) is pushed in the gap 412 and towards the rotary plate 230 between the two spring tabs 220, the ends 410 of the spring tabs 220 will expand outward, towards the two opposite sides. The bases 414 of the spring tabs 220 are secured to the rotary plate 230 via structures 400 on the rotary plate 230.

The material for the spring tabs 220 may be selected from plastic, metal, or a combination thereof. The spring tab(s) 210 are deformable yet resilient to facilitate locking and unlocking. In certain embodiments, the locking device 200 may include only a single spring tab 220. In other embodiments, the locking device 200 may include two or more spring tabs 220.

In FIG. 4C, the abutment block 240 is shaped with one thick end 424 that tapers to a thin edge 422, e.g., trapezoidal-shaped although it will be appreciated other shapes may be used. The thin edge 422, when assembled into the locking device 200, is pointed at the gap 412 between the two spring tabs 220. The thick end 424 includes a recessed surface 426, which abuts one end of the lower rod 260 when assembled. In certain embodiments, the recessed surface 426 is provided with one or more hook structures 428, which are used to connect with the end of the lower rod 260 and provide a rotational groove. This allows the lower rod 310 to rotate relative to the abutment block 240. The abutment block 240 may be made of plastic, metal, or other suitable materials.

The abutment block 240 further includes a pair of handles 430 provided on its two opposite sides. The pair of handles 430 can cooperate with elongated slots (e.g., the slots 432 on the bracket 268) such that the abutment block 240 is movable back and forth along a predetermined direction.

FIGS. 4D-4H illustrate various components of the sliding rod assembly 280, including, among other components, the lower rod 260, a spring 262, the upper rod 264, the rod housing 266, and the bracket 268.

The bracket 268 can be connected to the rotary plate 230 through the screw holes 408 on the rotary plate 230, for example, using one or more fasteners. The fasteners can be of any suitable type, such as screws (e.g., the screws 270), rivets, and/or adhesive to provide by a few examples. In other embodiments, the bracket 268 may be integrally formed with the rotary plate 230. The bracket 268 may be made of any suitable material, e.g., plastic or metal.

In the illustrated example, the bracket 268 includes two elongated slots 432 formed on two parallel side columns located on opposite sides, which serve to guide the movement of the abutment block 240 along an axial direction. Additionally, one end of the bracket 268 includes a through hole 474 that allows the upper rod 264 and the rod housing 266 to pass through. Moreover, the inner circumference of the through hole 474 is equipped with at least one notch 472, which can engage with at least one protrusion (e.g., the protrusion(s) 470 as shown in FIG. 4G) provided on the edge of the rod housing 266 to position the rod housing 266 during assembly. The rod housing 266, once placed in the designated position, can be secured to the bracket 268 by a friction fit formed between the at least one notch 472 and protrusion 470 or by other means such as, for example, by welding, riveting, adhesion, or other suitable methods. As will become apparent from the description that follows, during use, the rod housing 266 provides a counteracting force toward the spring tabs 220 to maintain the locked state.

FIG. 4D is a perspective view of the lower rod 260, in accordance with certain embodiments. From this perspective, the lower rod 260 has a base 436 at one end, which can be connected with the one or more hook structures 428 on the recessed surface 426 of the abutment block 240. This allows the lower rod 260 to connect with the abutment block 240 and enables the lower rod 260 to rotate relative to the abutment block 240. The other end of the lower rod 260, opposite the base 436, has a surface 440, which in the embodiment shown is uneven, e.g., wavy. The surface 440 is arranged opposing one end of the upper rod 264, where the end of the upper rod 264 has a surface 442 with a matching reciprocal wavy pattern to facilitate engagement of the pieces. In certain embodiments, as the lower rod 260 rotates relative to the upper rod 264, the contact between the surfaces 440 and 442 may transition between full engagement (when the peaks and valleys are aligned) and partial or reduced contact (when they are misaligned).

The spring 262, as shown in FIG. 4E, is disposed between the lower rod 260 and the upper rod 264. For example, a recessed hole 444 is formed at the center of the surface 440 of the lower rod 260, and a corresponding recessed hole 446 is formed at the center of the surface 442 of the upper rod 264. The opposite ends of the spring 262 may be seated in the recessed holes 444 and 446. Accordingly, when the surfaces 440 and 442 are fully engaged, the spring 262 is compressed to its maximum extent and is fully received in a cavity defined jointly by the recessed holes 444 and 446. During operation, the spring 262 continues to exert an outward biasing force on the surfaces 440 and 442, thereby tending to push the two surfaces apart. As a result, the press button 130 (e.g., the end of the upper rod 264) remains in a protruded state regardless of whether the locking device 200 is in the locked or unlocked status.

It will be noted that the use of the spring 262 is optional, and that the configurations of the recessed holes and on the upper and lower rods may vary. For example, the spring 262 may be omitted or replaced with another suitable resilient component. In some embodiments, a single recessed hole may be provided on either the lower rod 260 or the upper rod 264. In other embodiments, no recessed holes may be provided, in which case the surfaces 440 and 442 may not be in full contact in the fully engaged state.

The lower rod 260 includes a core cylindrical column 454 and an outer layer 450, both connected to the base 436. The core cylindrical column 454 and the upper rod 264 are designed to have the same diameter. The outer layer 450 includes one or more discrete, elongated strip-shaped plates 480 along the axial direction of the cylindrical column 454. In this example, the outer layer includes three plates 480, evenly distributed along the circumference of the cylindrical column 454 although it will be appreciated that the number and placement of plates may vary from the embodiment shown. The distance from the plates 480 to the axis of cylindrical column 454 corresponds to the radius of the rod housing 266, such that when assembled into the sliding rod assembly 280, the plates 480 contacts a lower edge 482 of the rod housing 266 shown in FIG. 4G.

FIG. 4F provides a perspective view of the upper rod 264, in accordance with certain embodiments. The end of the upper rod 264, opposite to the wavy surface 442, can serve as the press button 130 or be connected to the press button 130. The surface of the respective end of the upper rod 320 can be designed to be flat, wavy, or have other profiles, which is not limited in the present disclosure. In at least one embodiment, the side wall of the upper rod 264 is provided with at least one sliding groove 460.

FIG. 4G provides a perspective view of the rod housing 266, in accordance with certain embodiments. The inner side wall of the rod housing 266 is provided with at least one protrusion 462, which can be adapted to fit into the at least one sliding groove 460 on the side wall of the upper rod 264, allowing the upper rod 264 to slide axially relative to the rod housing 266.

Each of the lower rod 260, the upper rod 264, and the rod housing 266 may be made of plastic or metal.

From this perspective, the lower edge 482 of the side wall of the rod housing 266 is designed with a curved shape to guide the movement of the at least one plate 480 on the lower rod 260 during use. Specifically, the lower edge 482 is in contact with the at least one plate 480 on the lower rod 260 throughout use. Due to the upward (or outward) force exerted by the spring tabs 220, the at least one plate 480 on the lower rod 260 tends to move upward (or outward), while the rod housing 266 provides a downward (or inward) resisting force through the lower edge 482, as the rod housing 266 is fixed to the casing 110.

The lower edge 482 of the rod housing 266 includes a plurality of grooves configured to provide rotational limits. The grooves include first sections 484 having a first depth and second sections 452 having a second depth, which are alternately arranged along the lower edge 482. The first depth differs from the second depth. In one example, adjacent first sections 484 are spaced 120 degrees apart, with a similar arrangement for the second sections 452. When the lower rod 260 and the upper rod 264 are fully engaged, the plates 480 of the lower rod 260 are seated in the second sections 452. When the plates 480 of the lower rod 260 are seated in the first sections 484, the lower rod 260 and the upper rod 264 are spaced further apart.

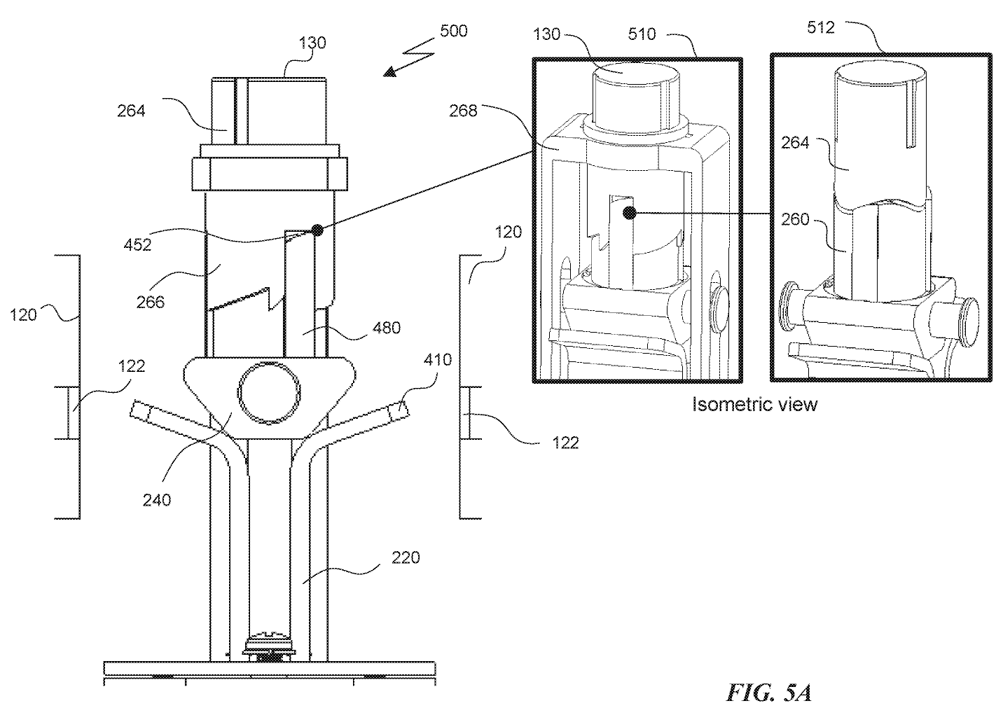

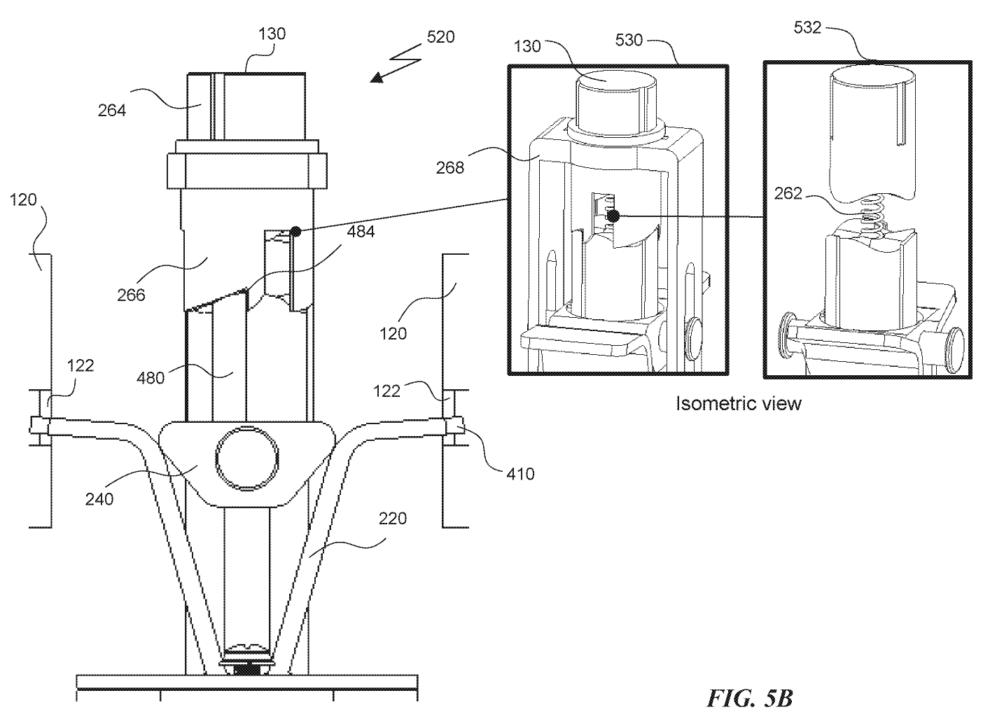

FIGS. 5A-5B illustrate the locking device 200 in a stable unlocked state and a stable locked state, respectively, in accordance with certain embodiments. In the illustrated example, the components as demonstrated in FIGS. 4A-4H are utilized to assemble the locking device 200. However, it should be noted that variations of one or more components discussed above can be used to assemble a locking device 200 to facilitate the functions described herein.

In FIG. 5A, the locking device 200 is shown in a stable unlocked state 500. The locking device 200 is positioned between the side walls of the modular devices 120. The side walls of the modular devices 120 are provided with slots 122 configured to receive the ends 410 of the spring tabs 220. In the unlocked state 500, the spring tabs 220 are not pushed open by the abutment block 240, such that the spring tabs 220 remain in a retracted state, withdrawn from the slots 122. At this time, the lower rod 260 and the upper rod 264 are fully engaged, with the plates 480 of the lower rod 260 seated in the second sections 452 of the rod housing 266. Additionally, the upper rod 264 slides upward out of the rod housing 266, causing the press button 130 to protrude (e.g., from the front panel 112). Insets 510 and 512 provide enlarged partial isometric views, illustrating the sliding rod assembly 280 and schematically showing it with and without the bracket 268 and the rod housing 266, respectively.

In FIG. 5B, the locking device 200 is shown in a stable locked state 520. In the locked state 520, the spring tabs 220 are pushed open by the abutment block 240, such that the ends 410 of the spring tabs 220 are inserted into the slots 122. At this time, the lower rod 260 and the upper rod 264 are disengaged, with the plates 480 of the lower rod 260 seated in the first sections 484 of the rod housing 266. Additionally, the upper rod 264 slides downward relative to the rod housing 266, causing the press button 130 to be pressed into the front panel 112. Insets 530 and 532 provide enlarged partial isometric views, illustrating the sliding rod assembly 280 and schematically showing it with and without the bracket 268 and the rod housing 266, respectively. Additionally, inset 532 illustrates the spring 262 positioned between the lower rod 260 and the upper rod 264.

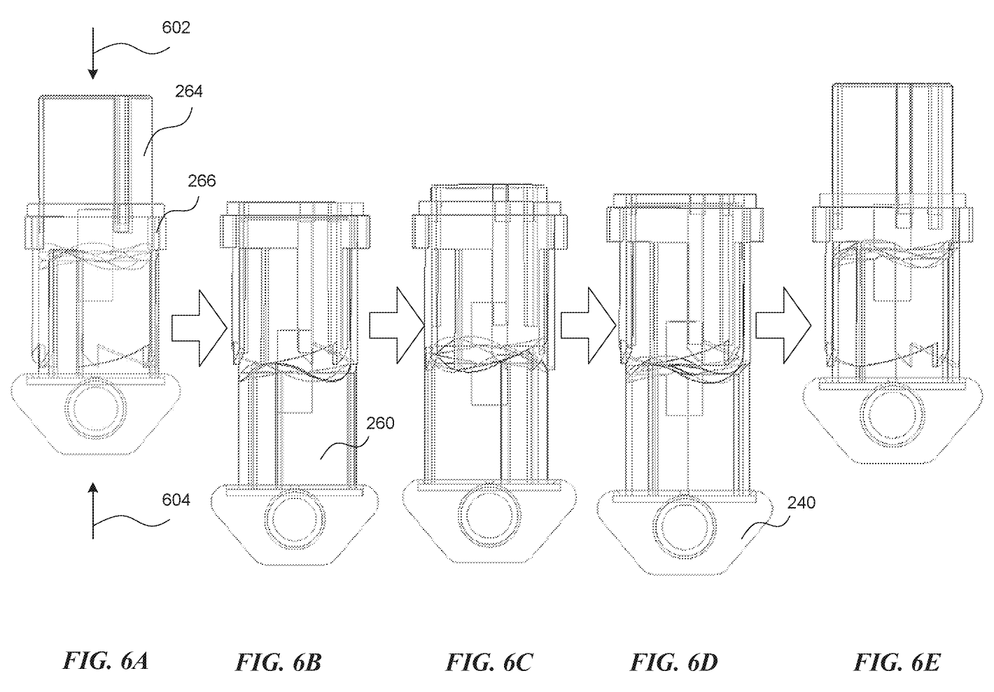

FIGS. 6A-6E illustrate a dynamic process of using the locking device 200. FIG. 6A represents an initial unlocked state, corresponding to the stable unlocked state 500 shown in FIG. 5A. Subsequently, the locking device 200 is pressed until it reaches the stable locked state 520 shown in FIG. 6C. Finally, continued pressing returns the locking device 200 to the stable unlocked state 500, corresponding again to FIG. 5A. Arrow 602 indicates the pressing direction (e.g., applied by a user’s hand), while arrow 604 indicates the biasing direction (e.g., caused by the spring tabs 220).

During the dynamic process, the position of the rod housing 266 is used as a reference, as the rod housing 266 remains stationary throughout the process. The rod housing 266 is fixed to the bracket 268, which is secured to the casing 110 (e.g., via internal frames).

From FIG. 6A to FIG. 6B, the upper rod 264 is pushed downward (e.g., by the user hand). As the rod housing 266 provides a rotational limit, the upper rod 264 does not rotate. During this downward movement, contact with the upper rod 264 causes the lower rod 260 to rotate by a certain angle. In the meantime, the sliding rod assembly 280 pushes the abutment block 240 downward, thereby forcing the spring tabs 220 to open.

From FIG. 6B to FIG. 6C, after the user’s hand is released, the biasing force 604 of the spring tabs 220 pushes the abutment block 240 and the sliding rod assembly 280 upward. Because the lower rod 260 rotated by a certain angle during the downward pressing, upon upward rebound, the plates 480 of the lower rod 260 engage the rotational limit grooves of the rod housing 266 (e.g., the first sections 484), thereby maintaining the displaced position.

From FIG. 6C to FIG. 6D, when the upper rod 264 is pressed again, the lower rod 260 rotates by an additional angle. From FIG. 6D to FIG. 6E, upon upward rebound, the plates 480 of the lower rod 260 engage the next rotational limit grooves of the rod housing 266 (e.g., the second sections 452), thereby returning to the unpressed state.

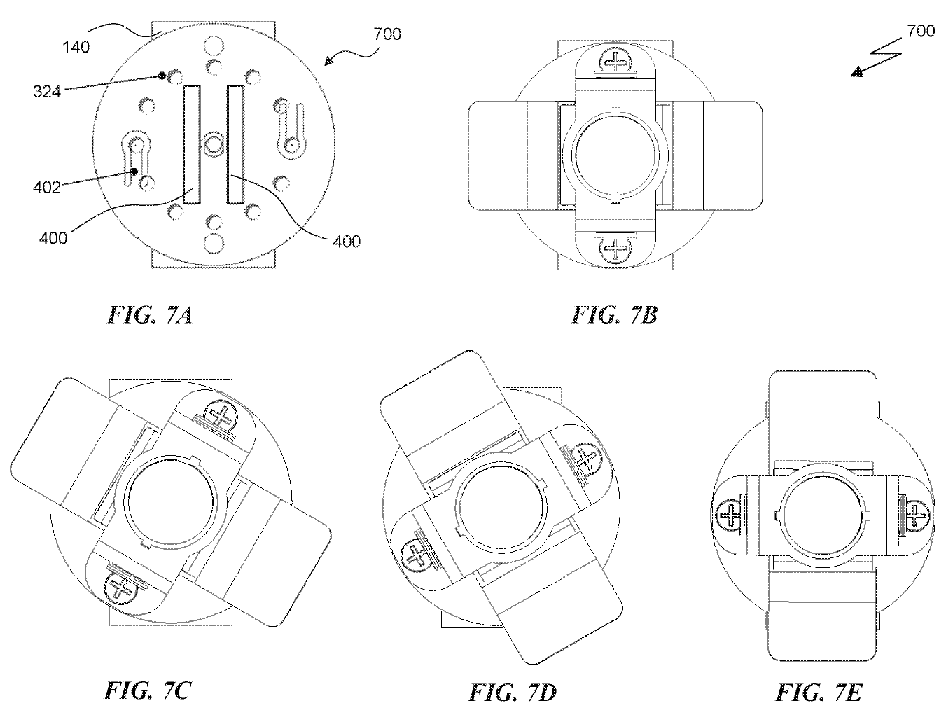

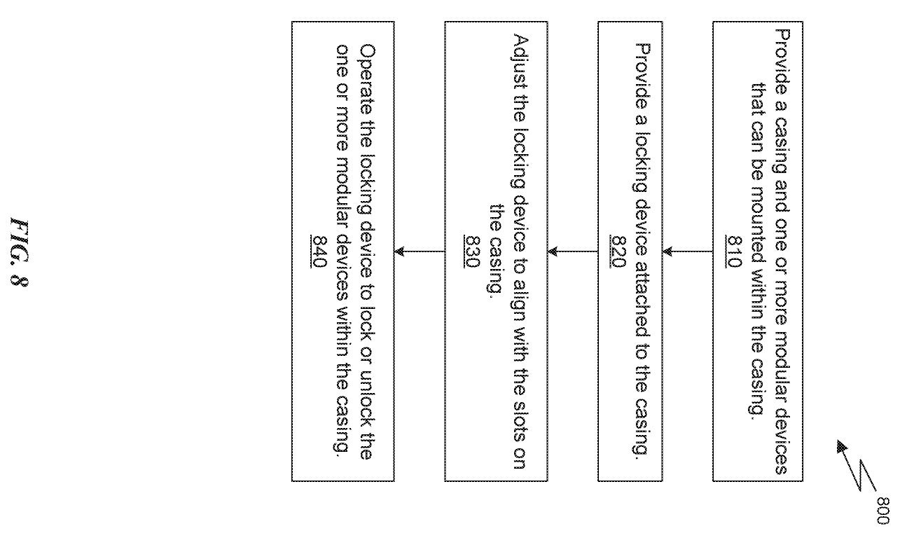

FIG. 7A illustrates a rotation assembly 700, in accordance with certain embodiments. The rotation assembly 700 includes the rotary plate 230 and the base frame 218, which are concentrically aligned. FIG. 7A shows features on the outer side of the rotary plate 230, including structures 400 configured to secure the spring tabs 220. Additionally, FIG. 7 provides a perspective view of features on the inner side of the rotary plate 230, including U-shaped spring arm structures 402, as well as the opposing surface of the base frame 218, which is provided with hemispherical structures 324. The rotary plate 230 is rotatable relative to the base frame 218, and the U-shaped spring arm structures 402 cooperate with the hemispherical structures 324 to provide rotational limits.

FIGS. 7B-7E illustrate example rotational operation of the rotation assembly 700. The locking assembly 250 is mounted on the rotation assembly 700. It can be seen that the rotation assembly 700 allows the locking device 200 to be positioned at multiple rotational positions. Accordingly, in addition to the arrangement of the slots 122 shown in FIG. 1A, the locking device 200 can cooperate with slots arranged at other angles (e.g., on the top and bottom side walls) to lock the modular devices 120.

FIG. 8 is a flow chart illustrating a method 800 for assembling a computer/server system utilizing a locking device 200, in accordance with certain embodiments. Method 800 may be used to install any of the locking devices disclosed herein. Method 800 may be performed alone or in combination with other processes in the present disclosure. It will be recognized that method 800 may be performed in any suitable environment and in any suitable order except where otherwise apparent. Alternative steps/stages may be performed instead of or in addition to those shown, and some steps/stages may be omitted entirely. As an example, method 800 is described with reference to the locking device 200, as shown in FIGS. 2A-2D, installed in the casing 110, as illustrated in FIG. 1A.

At stage 810, a casing 110 and one or more modular devices 120 are provided. The one or more modular devices 120 can be mounted inside the casing 110. For example, the one or more modular devices 120 can be configured as units housed within movable containers. The side panel of the one or more modular devices 120 is provide with a slot 122.

At stage 820, a locking device 200 is provided. The locking device 200 includes one or more spring tabs, such as the spring tabs 220. For example, the one or more spring tabs 220 can engage with the slot(s) 122 on the modular device(s) 120 to lock the modular device(s) 120 in place within the casing 110. When disengaged from the slot(s) 122, the modular device(s) 120 can be removed from the casing 110.

The locking device 200 includes an abutment block (e.g., the abutment block 240) and a sliding rod assembly (e.g., the sliding rod assembly 280), both aligned along an axial direction. The abutment block is configured to push the one or more spring tabs, causing the spring tab(s) to engage or disengage with the slot(s). The abutment block and the sliding rod assembly can move along the axial direction in response to a force applied to the press button 130 and/or an opposing force (e.g., exerted by the one or more spring tabs 220).

Once assembled into the locking device 200, one end (e.g., the thin edge 422) of the abutment block is oriented toward the at least one spring tab, while the other end (e.g., the thick end 424) of the abutment block is connected to a lower rod in the rod assembly. The lower rod, the upper rod, and the rod housing are arranged along the axial direction (e.g., as depicted in FIGS. 2A-2D).

In certain embodiments, a bracket (e.g., the bracket 268) is provided to further restrict the axial movement of the abutment block and the sliding rod assembly (e.g., as shown in FIG. 2C).

The locking device 200 includes the subassembly 216, configured to be slidable in a direction defined by the base bracket 140, and the rotation assembly 700, allowing the locking device 200 to be positioned at multiple rotational positions.

At stage 830, the locking device 200 is adjusted to align with the slots on the casing. For example, as shown in FIG. 1A, the locking device 200 can be adjusted along a vertical direction, as enabled by the subassembly 216. Additionally, the locking device 200 can be rotated, as enabled by the rotation assembly 700. In this manner, the ends 410 of the spring tabs 220 can be aligned with the shape of the slots 122 on the side walls of the modular devices 120.

At stage 840, the locking device 200 can be operated by a user to lock or unlock one or more modular devices 120 within the casing 110. In certain embodiments, the locking device 200 operates according to the process illustrated in FIGS. 6A-6E, thereby providing a locked state (e.g., as shown in FIG. 5B) and an unlocked state (e.g., as shown in FIG. 5A).

As such, the locking device disclosed herein offers several advantages. The locking device incorporates a quick-press, snap-on locking and quick-release mechanism, enabling the fast assembly and disassembly of removable modular devices in computer or server systems. The locking device can be operated with a simple press to lock or unlock the modular device(s) from the casing, making maintenance more convenient. Additionally, the compact structural design of the locking device minimizes the required installation space. In certain embodiments, since the locking device is designed with an elongated structure, the locking device can accommodate different rod lengths (e.g., for the lower rod 260 and/or the upper rod 264), enabling efficient operation even in narrow spaces.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Exemplary embodiments are described herein. Variations of those embodiments may become apparent to those of ordinary skill in the art upon reading the foregoing description. The inventors expect skilled artisans to employ such variations as appropriate, and the inventors intend for the embodiments to be practiced otherwise than as specifically described herein. Accordingly, embodiments include all modifications and equivalents of the subject matter recited in the claims appended hereto as permitted by applicable law. Moreover, any combination of the above-described elements in all possible variations thereof is encompassed by the embodiments unless otherwise indicated herein or otherwise clearly contradicted by context.

1. A locking device, comprising:
an adjustable base assembly comprising a rotation assembly and a linear guide rail; and
a locking assembly mounted on the adjustable base assembly, the locking assembly comprising:
one or more spring tabs configured to engage and disengage with one or more slots provided on one or more frame panels;
an abutment block, wherein the abutment block is movable in an axial direction relative to the one or more spring tabs and configured to push, in response to a force, the one or more spring tabs outward, thereby causing engagement of the one or more spring tabs with the one or more slots, and wherein the abutment block is connected to a sliding rod assembly; and
the sliding rod assembly configured to move with the abutment block and provide a first stable position for a locked state and a second stable position for an unlocked state,
wherein the adjustable base assembly is configured to adjust a position and an orientation of the locking assembly relative to the one or more slots.

2. The locking device of claim 1, wherein the sliding rod assembly comprises:
a lower rod, wherein one end of the lower rod is connected to one end of the abutment block, and the lower rod is rotatable relative to the abutment block;
an upper rod, wherein the other end of the lower rod is in contact with one end of the upper rod; and
a rod housing fitted over the upper rod,
wherein the lower rod, the upper rod, and the rod housing are aligned along the axial direction, and
wherein the lower rod and the upper rod are configured to slide along the axial direction relative to the rod housing.

3. The locking device of claim 2, wherein the lower rod comprises a wavy surface on one end, the upper rod comprises a reciprocal wavy surface on one end, and the wavy surface of the lower rod is oriented toward the reciprocal wavy surface of the upper rod in the sliding rod assembly and the reciprocal wavy surface of the upper rod is configured to mate and engage the wavy surface of the low rod.

4. The locking device of claim 2, wherein the sliding rod assembly further comprises a spring, wherein the spring is positioned between the lower rod and the upper rod.

5. The locking device of claim 4, wherein at least one of the lower rod or the upper rod comprises a recessed hole, the recessed hole being configured to receive the spring when compressed.

6. The locking device of claim 2, wherein the lower rod comprises a cylindrical column and at least one plate attached to side wall of the cylindrical column, wherein a side wall of the rod housing comprises a curved edge, and wherein in the sliding rod assembly, the at least one plate on the lower rod is in contact with the curved edge of the rod housing.

7. The locking device of claim 6, wherein the curved edge of the rod housing is provided a plurality of grooves to provide rotational limits, wherein the plurality of grooves comprise first sections having a first depth and second sections having a second depth, the first and second sections are alternately arranged along the curved edge of the rod housing.

8. The locking device of claim 7, wherein the at least one plate on the lower rod comprises three plates spaced apart by 120 degrees, and wherein the curved edge of the rod housing is provided with three first sections and three second sections.

9. The locking device of claim 1, wherein one edge along the linear guide rail comprises a series of repetitive structures configured to provide positional limits to the adjustable base assembly along a linear direction.

10. The locking device of claim 1, wherein the rotation assembly comprises a plurality of hemispherical structures and one or more spring arm structures configured to provide rotational limits to the adjustable base assembly.

11. The locking device of claim 1, wherein the abutment block further comprises at least one handle positioned on at least one side of the abutment block, wherein a bracket mounted outside the sliding rod assembly comprises at least one elongated slot configured to guide movement of the handle on the abutment block.

12. The locking device of claim 1, wherein the one or more spring tabs comprise a single spring tab, configured to lock a single modular device within a casing.

13. The locking device of claim 1, wherein the one or more spring tabs comprise two or more spring tabs, configured to lock two or more modular device within a casing at the same time.

14. The locking device of claim 1, wherein the one or more spring tabs are fixed to a casing of a computer system or a server system through the adjustable base assembly, and wherein one or more modular devices are locked in the casing of the computer system or the server system based on the one or more spring tabs engaging with the one or more slots on the one or more modular devices.

15. A framework for housing one or more computer systems, comprising:
a casing;
one or more modular devices provided with one or more slots, wherein the one or more modular devices are removable from the casing; and
a locking device configured to lock and unlock the one or more modular devices within the casing,
wherein the locking device comprises:
an adjustable base assembly comprising a rotation assembly and a linear guide rail; and
a locking assembly mounted on the adjustable base assembly, the locking assembly comprising:
one or more spring tabs configured to engage and disengage with one or more slots;
an abutment block, wherein the abutment block is movable in an axial direction relative to the one or more spring tabs and configured to push, in response to a force, the one or more spring tabs outward, thereby causing engagement of the one or more spring tabs with the one or more slots, and wherein the abutment block is connected to a sliding rod assembly; and
the sliding rod assembly configured to move with the abutment block and provide a first stable position for a locked state and a second stable position for an unlocked state,
wherein the adjustable base assembly is configured to adjust a position and an orientation of the locking assembly relative to the one or more slots.

16. The framework of claim 15, wherein the sliding rod assembly comprises:
a lower rod, wherein one end of the lower rod is connected to one end of the abutment block, and the lower rod is rotatable relative to the abutment block;
an upper rod, wherein the other end of the lower rod is in contact with one end of the upper rod; and
a rod housing fitted over the upper rod,
wherein the lower rod, the upper rod, and the rod housing are aligned along the axial direction, and
wherein the lower rod and the upper rod are configured to slide along the axial direction relative to the rod housing.

17. The framework of claim 16, wherein the lower rod comprises a wavy surface on one end, the upper rod comprises a reciprocal wavy surface on one end, and the wavy surface of the lower rod is oriented toward the reciprocal wavy surface of the upper rod in the sliding rod assembly and the reciprocal wavy surface of the upper rod is configured to mate and engage the wavy surface of the low rod.

18. The framework of claim 16, wherein the sliding rod assembly further comprises a spring, wherein the spring is positioned between the lower rod and the upper rod.

19. The framework of claim 18, wherein at least one of the lower rod or the upper rod comprises a recessed hole, the recessed hole being configured to receive the spring when compressed.

20. A method for assembling a computer or server system comprising one or more modular devices that are removable from a casing, comprising:
providing the casing of the computer or server system and the one or more modular devices, wherein the one or more modular devices are provided with one or more slots;
providing a locking device connected to the casing, wherein the locking device comprises:
an adjustable base assembly comprising a rotation assembly and a linear guide rail; and
a locking assembly mounted on the adjustable base assembly, the locking assembly comprising:
one or more spring tabs configured to engage and disengage with the one or more slots;
an abutment block, wherein the abutment block is movable in an axial direction relative to the one or more spring tabs and configured to push, in response to a force, the one or more spring tabs outward, thereby causing engagement of the one or more spring tabs with the one or more slots, and wherein the abutment block is connected to a sliding rod assembly; and
the sliding rod assembly configured to move with the abutment block and provide a first stable position for a locked state and a second stable position for an unlocked state,
wherein the adjustable base assembly is configured to adjust a position and an orientation of the locking assembly relative to the one or more slots;
adjust a position and a rotation of the locking device to align with the one or more slots; and
operate the locking device to lock or unlock the one or more modular devices to the casing.
